(19) United States
(12) Patent Application Publication
(10) Pub. No.: US 2010/0196599 A1
(43) Pub. Date: Aug. 5, 2010

(54) STAGGERED DUAL PROCESS CHAMBERS USING ONE SINGLE FACET ON A TRANSFER MODULE

(76) Inventors: Hari K Ponnekanti, San Jose, CA (US); Karl M. Brown, Los Gatos, CA (US); Jibing Zeng, Shanghai (CN); Yin Bai, Shaanxi (CN); Fang Lin, Shaanxi (CN); Shaowen Lei, Shaanxi (CN)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/066,383

(22) PCT Filed: Dec. 20, 2007
(86) PCT No.: PCT/CN07/03707

§ 371 Date: Apr. 14, 2010

(51) Int. Cl. C23C 16/44; H01L 21/677; C23C 16/00

(52) U.S. Cl. 427/248.1; 414/217; 118/719

(57) ABSTRACT

A method and apparatus for increasing the throughput of substrate processing systems is provided. A processing chamber configured for attachment to a cluster tool for processing substrates has dual, staggered processing regions. The processing regions are isolated from one another such that a substrate may be processed in each region simultaneously.

### BACKGROUND OF THE INVENTION

1. Field of the Invention

Embodiments of the present invention generally relate to an integrated processing system configured to process substrates. More particularly, the invention relates to a staggered dual process chamber configured for attachment to a transfer module of a cluster tool.

2. Description of the Related Art

Substrates are commonly processed in multi-chamber processing systems, or cluster tools, capable of processing substrates in a controlled environment. A typical cluster tool includes a system with a transfer module housing a substrate transfer robot configured to transport substrates between a load lock chamber and multiple vacuum processing chambers. For example, a transfer module may be connected to one or more physical vapor deposition (PVD) chambers and/or chemical vapor deposition chambers (CVD) configured for depositing layers on the substrate.

However, substrates and layers deposited thereon absorb moisture and impurities, which must be removed, or degassed, prior to further processing. The degassing process is performed in an additional process, or degas, chamber attached to the cluster tool. Thus, the degassing process significantly increases the cost of the processing system by occupying valuable space around the transfer module.

Furthermore, because of the extended time period needed for degassing prior to PVD processing, in particular, the degassing step can significantly reduce the overall process throughput. One prior art approach that has been considered for solving the throughput problem is to provide parallel degassing chambers. This approach provides two degas chambers in a substrate processing apparatus for each PVD processing chamber. However, this solution requires additional transfer module attachment ports and significantly increases the space required for the cluster tool.

Another prior art approach that has been attempted for solving this problem is a multi-slot, continuous operation, degas chamber. However, this approach results in problems with cross contamination of substrates due to outgassing from a freshly delivered substrate.

Accordingly, a need exists for a degas chamber configuration that increases throughput of a processing system while minimizing the space required for its use and eliminating the potential of cross contamination.

### SUMMARY OF THE INVENTION

In one embodiment of the present invention, a substrate processing chamber comprises a first processing volume and a second processing volume vertically stacked atop the first processing volume and centrally offset from the first processing volume. The first and second processing volumes are isolated from one another such that no cross contamination occurs during simultaneous processing.

In another embodiment, a substrate processing chamber comprises a unitary main chamber body configured to form an upper processing region and a lower processing region, wherein the upper processing region overlaps the lower processing region, a removable chamber lid configured for airtight connection with the unitary main chamber body atop the upper processing region, and a chamber bottom member configured for airtight connection with the unitary main chamber body underlying the lower processing region, wherein the chamber bottom member is configured to pivotally engage the unitary main chamber body.

In another embodiment, a substrate processing system comprises a load lock chamber, a transfer module, and a processing chamber, wherein the processing chamber comprises a port block and a main chamber body. The main chamber body forms an upper processing region overlapping a lower processing region, and the upper and lower processing regions are isolated from one another and centrally offset.

In yet another embodiment of the present invention, a method for degassing substrates in a cluster tool comprises transferring a first substrate from a load lock chamber to an upper processing region of a degas chamber via a transfer robot, processing the first substrate in the upper processing region of the degas chamber, transferring a second substrate from the load lock chamber to a lower processing region of the degas chamber via the transfer robot while the first substrate is being processed, and starting the processing of the second substrate in the lower processing region prior to completing the processing of the first substrate. The upper processing region overlaps and is centrally offset from the lower processing region.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic, plan view of a cluster tool in accordance with one embodiment of the present invention.

FIG. 2 is a schematic, cross-sectional, side view of an embodiment of a degas chamber in accordance with the present invention.

FIG. 3 is a schematic, isometric, partially exploded view of an embodiment of a degas chamber in accordance with the present invention.

### DETAILED DESCRIPTION

The present invention generally provides an apparatus and method for increasing the throughput of substrate processing systems. Embodiments of the present invention include a dual, staggered degas chamber configured to separately degas two substrates simultaneously or during overlapping time periods, wherein each substrate is degassed in a process volume that is isolated from the other.

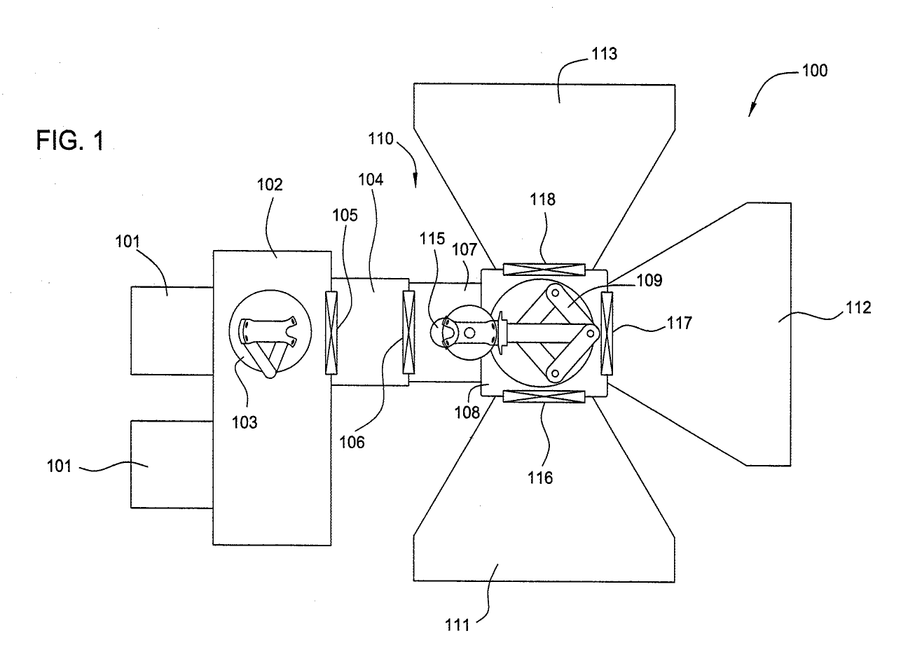

FIG. 1 is a schematic, plan view of a cluster tool 100 in accordance with one embodiment of the present invention. Generally, the cluster tool 100 comprises multiple processing chambers coupled to a single transfer module.

The cluster tool 100 comprises a factory interface 102 in selective communication with a load lock chamber 104. One or more pods 101 are configured to store and transport substrates. A factory interface robot 103 is disposed in the factory interface 102. The factory interface robot 103 is configured to transfer substrates between the pods 101 and the load lock chamber 104.

The load lock chamber 104 provides a vacuum interface between the factory interface 102 and a transfer module 110. An internal region of the transfer module 110 is typically maintained at a vacuum condition and provides an intermediate region to shuttle substrates between the load lock chamber 104 and processing chambers 111, 112, 113 as well as between the processing chambers 111, 112, 113.

In one embodiment, the transfer module 110 is divided into two parts to minimize the footprint of the cluster tool 100. In one embodiment, the transfer module 110 comprises a transfer chamber 108 and a vacuum extension chamber 107. The transfer chamber 108 and the vacuum extension chamber 107 are coupled together and are in fluid communication with one another to form an inner volume in the transfer module 110. The inner volume of the transfer module 110 may be maintained at a low pressure or vacuum condition during processing. The load lock chamber 104 may be connected to the factory interface 102 and the vacuum extension chamber 107 via slit valves 105 and 106, respectively.

The transfer chamber 108 is configured to house a transfer robot 109 and provide interfaces to a plurality of processing chambers. Additionally the transfer chamber 108 may provide an interface for a pass through chamber for connecting to additional transfer modules to extend the cluster tool 100. In one embodiment, the transfer chamber 108 may be a polygonal structure having a plurality of sidewalls, a bottom, and a lid. The plurality of sidewalls may have openings formed therein and may be configured to connect with processing chambers, vacuum extension chambers, or pass through chambers. The transfer chamber 108, shown in FIG. 1, has a square horizontal profile and is coupled to processing chambers 111, 112, 113, and the vacuum extension chamber 107. In one embodiment, the transfer chamber 108 may be in selective communication with the processing chambers 111, 112, and 113 via slit valves 116, 117, and 118, respectively. In a further embodiment, the transfer robot 109 may be mounted in the transfer chamber 108 at a robot port formed on the bottom of the transfer chamber 108.

The transfer robot 109 is disposed in an internal volume of the transfer chamber 108 and is configured to shuttle substrates in a substantially horizontal orientation between the processing chambers 111, 112, 113 and to and from the load lock chamber 104 through the vacuum extension chamber 107. In one embodiment, the transfer robot 109 may comprise two blades for holding substrates, each blade mounted on an independently controllable robot arm coupled to the same robot base. In another embodiment, the transfer robot 109 is configured to control the vertical elevation of the blades.

The vacuum extension chamber 107 may be configured to provide an interface between a vacuum system and the transfer chamber 108. In one embodiment, the vacuum extension chamber 107 comprises a bottom, a lid, and sidewalls. A pressure modification port 115 may be formed on the bottom of the vacuum extension chamber 107 and may be configured to adapt to a vacuum pump system, such as a cryogenic pump, which may be required to maintain high vacuum in the transfer chamber 108. The pressure modification port 115 may be blocked when only a smaller vacuum pump is needed. A smaller vacuum pump may be coupled to the transfer chamber 108 through a smaller port formed in the transfer chamber 108.

Openings may be formed on the sidewalls of the vacuum extension chamber 107 such that it is in fluid communication with the transfer chamber 108, and in selective communication with chambers connected thereto, such as load lock chambers, pass through chambers, and processing chambers.

In one embodiment, the cluster tool 100 may be configured to deposit a film on a substrate using physical vapor deposition (PVD) process.

PVD may be performed in a sealed chamber having a pedestal for supporting a substrate disposed thereon. The pedestal typically includes a substrate support that has electrodes disposed therein to electrostatically hold the substrate against the substrate support during processing. A target, generally comprised of a material to be deposited on the substrate, is supported above the substrate, typically fastened to a top of the chamber. Plasma formed from a gas, such as argon, is supplied between the substrate and the target. The target is biased, causing ions within the plasma to be accelerated toward the target. Ions impacting the target cause material to become dislodged from the target. The dislodged material is attracted toward the substrate, and a film of the material is deposited thereon.

In one embodiment, the cluster tool 100 may comprise a degas chamber, a pre-clean chamber, and a PVD chamber connected to the transfer chamber 108 at positions for processing chambers 111, 112, and 113, respectively. In such a system, the time needed to adequately degas a substrate may far exceed the time needed to pre-clean or deposit a film on the substrate. Therefore, in one embodiment of the present invention, a staggered, dual degas chamber may be used.

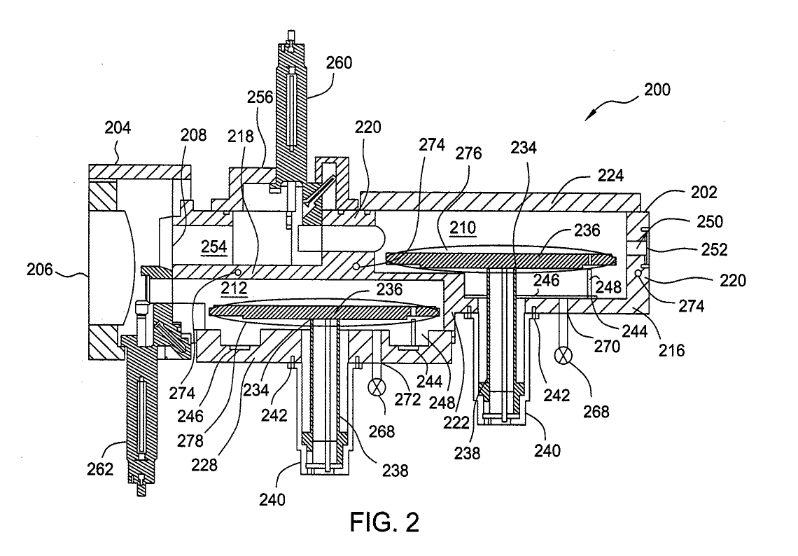

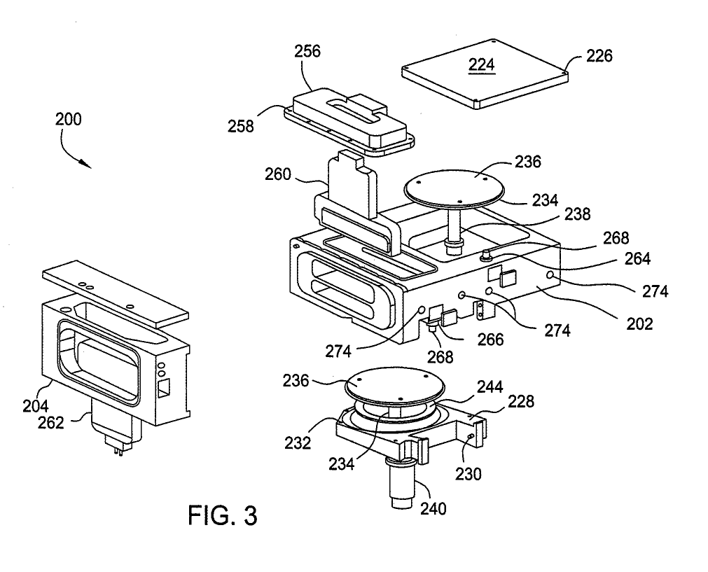

FIG. 2 is a schematic, cross-sectional side view and FIG. 3 is a schematic, isometric, partially exploded view of an embodiment of a degas chamber 200 in accordance with the present invention. Degas chamber 200 may comprise a main chamber body 202 attached to a port block 204. The port block 204 may include a transfer module interface 206 and a chamber interface 208. The transfer module interface 206 may attach to a transfer module, such as the transfer module 110 in FIG. 1, such that a substrate may be transferred to or from the chamber body 202 via a transfer robot, such as the transfer robot 109 in FIG. 1, through the port block 204.

The main chamber body 202 may comprise an upper chamber volume 210 and a lower chamber volume 212, which may be isolated from one another and separately contained in an overlapping fashion as shown in FIG. 2. The main chamber body 202 may be further configured to simultaneously function as an upper chamber bottom 216, a lower chamber top 218, upper chamber walls 220, and lower chamber walls 222. In one embodiment, the main chamber body 202 may be formed from a single block of aluminum or other suitable material.

The upper chamber volume 210 may be enclosed by the upper chamber bottom 216, the upper chamber walls 220, and an upper chamber lid 224. The upper chamber lid 224 may be removably attached via fastening members 226, such as screws or other suitable fasteners. Thus, the upper chamber lid 224 may be removed for access to the interior of the upper chamber volume 210 for maintenance and repair.

The lower chamber volume 212 may be enclosed by the lower chamber top 218, the lower chamber walls 222, and a lower chamber bottom 228. The lower chamber bottom 228 may be pivotally attached by pin members 230 and fastening members 232, such as screws or other suitable fasteners. Thus, the lower chamber bottom 228 may be pivoted to an open position for access to the interior of the lower chamber volume 212 for maintenance and repair.

Additionally, the chamber 200 may comprise a substrate support heater 234 disposed in the upper chamber volume 210 and another substrate support heater 234 disposed in the lower chamber volume 212. Each substrate support heater 234 comprises a platen portion 236 and a pedestal portion 238. The platen portion 236 may be comprised of a metallic or ceramic material. The pedestal portion 238 may include conduits disposed therethrough for electrical wiring and the like. Each pedestal portion 238 may be supported by a heater support sleeve 240 removably attached to the chamber body 202 via fastening members 242.

The chamber 200 may also comprise a substrate lifting device 244 disposed in the upper chamber volume 210 and another substrate lifting device 244 disposed in the lower chamber volume 212. Each substrate lifting device 244 may include a lift ring 246 and a plurality of lift pins 248. The lift pins 248 may be aligned with apertures in the platen portion 236 of the substrate support heater 234 such that the lift pins 248 may extend therethrough for engagement with a substrate.

In one embodiment, at least one of the upper chamber walls 220 may have an aperture 250 formed therethrough having a transparent covering member 252 for use as an upper substrate viewing port.

Further, chamber 200 may include an upper substrate access volume 254, enclosed by the lower chamber top 218, upper chamber walls 220, and an access lid 256. The access lid 256 may be removably attached via fastening members 258. Additionally, access lid 256 may have an aperture formed therethrough for incorporation with an upper slit valve 260. Thus, the upper slit valve 260 may selectively allow transfer of a substrate from a transfer module, such as the transfer module 110 in FIG. 1, to the upper chamber volume 210 via port block 204 and access volume 254.

The port block 204 may have an aperture formed therethrough for incorporation of a lower slit valve 262. Therefore, the lower slit valve 262 may selectively allow transfer of a substrate from a transfer module, such as the transfer module 110 in FIG. 1, to the lower chamber volume 212 via port block 204.

In one embodiment chamber 200 may include an upper diffuser port 264 in fluid communication with the upper chamber volume 210. The chamber 200 may also include a lower diffuser port 266 in fluid communication with the lower chamber volume 212. Both the upper diffuser port 264 and the lower diffuser port 266 may each be individually coupled to a valve 268, which is connected to a gas source, such as an inert gas source. The valves 268 may selectively allow gas flow into the upper chamber volume 210 and/or the lower chamber volume 212 as desired.

Additionally, chamber 200 may include an upper vacuum port 270 in fluid communication with the upper chamber volume 210. The chamber 200 may also include a lower vacuum port 272 in fluid communication with the lower chamber volume 212. Both the upper vacuum port 270 and the lower vacuum port 272 may each be individually coupled to a valve 268, in turn, connected to a vacuum source, such as a roughing pump, a turbomolecular pump, or a cryogenic pump.

In one embodiment, chamber 200 may include chamber cooling channels 274, which may be connected to a fluid cooling source, such as a water cooling source, for selective thermal management of the chamber body 202.

In one embodiment, chamber 200 may include an upper gauge port 276 in one of the upper walls 220 and a lower gauge port 278 in one of the lower walls 222. The upper and lower gauge ports 276 and 278 may be in fluid communication with any of a variety of gauges for monitoring the upper and lower chamber volumes 210 and 212, such as a residual gas analyzer.

In process, an embodiment of the degas chamber 200 may be used in conjunction with a cluster tool, such as the cluster tool 100 in FIG. 1, to selectively and individually, dynamically degas two substrates either simultaneously or for overlapping time periods, each in its own isolated environment.

For instance, transfer robot 109 may retrieve a substrate for processing. The transfer robot 109 may then transfer the substrate through the upper slit valve 260 onto the lift pins 248 in the upper chamber volume 210 for dynamic degassing. As the substrate is heated via the heater 234, a gas, such as argon, is delivered through the upper diffuser port 264 through the valve 268. The gas flows across the surface of the substrate and is removed along with moisture or other contaminants through the upper vacuum port 270.

Accordingly, at a specified point during the upper chamber process, the transfer robot 109 may retrieve another substrate for processing. The transfer robot 109 may then transfer the substrate through the lower slit valve 262 onto the lift pins 248 in the lower chamber volume 212 for dynamic degassing. As the substrate is heated via heater 234, a gas, such as argon, is delivered through the lower diffuser port 266 via the valve 268. The gas flows across the surface of the substrate and is removed along with moisture or other contaminants through lower vacuum port 272.

Therefore, two separate substrates may each be isolated and degassed simultaneously or during overlapping time periods as necessary for maximizing throughput of the substrate processing system. Moreover, because each substrate is isolated while being processed, no cross contamination occurs during transfer or processing of the other substrate. Further, chamber 200 may accomplish this task with a minimal overall footprint by staggering the upper chamber volume 210 and the lower chamber volume 212. Thus, the degas chamber 200 may significantly improve throughput without drastically increasing the space and cost requirements for the substrate processing system.

While the foregoing is directed to embodiments of the present invention, other and further embodiments of the invention may be devised without departing from the basic scope thereof, and the scope thereof is determined by the claims that follow.

1. A substrate processing chamber, comprising:
a first processing volume; and
a second processing volume vertically stacked atop the first processing volume and centrally offset from the first processing volume,
wherein the first and second processing volumes are isolated from one another such that no cross contamination occurs during simultaneous processing.

2. The substrate processing chamber of claim 1, further comprising:
a substrate support heater configured within the first processing volume; and
a substrate support heater configured within the second processing volume,
wherein each substrate support heater comprises a pedestal portion and a platen portion.

3. The substrate processing chamber of claim 2, further comprising a chamber lid covering the second processing volume, wherein the chamber lid is removable.

4. The substrate processing chamber of claim 2, further comprising a chamber bottom underlying the first process volume, wherein the chamber bottom pivots to allow access to the second processing volume.

5. The substrate processing chamber of claim 2, further comprising:
a substrate lifting device configured within the first processing volume; and
a substrate lifting device configured within the second processing volume,
wherein each substrate lifting device comprises a plurality of lift pins configured to extend through apertures configured in each substrate support heater platen portion.

6. A substrate processing chamber, comprising:
a unitary main chamber body configured to form an upper processing region and a lower processing region, wherein the upper processing region overlaps the tower processing region;
a removable chamber lid configured for airtight connection with the unitary main chamber body atop the upper processing region; and
a chamber bottom member configured for airtight connection with the unitary main chamber body underlying the lower processing region, wherein the chamber bottom member is configured to pivotally engage the unitary main chamber body.

7. The substrate processing chamber of claim 6, further comprising an upper slit valve configured to selectively allow transfer of a substrate into the upper processing region.

8. The substrate processing chamber of claim 7, further comprising:
a port block, wherein the port block is configured to allow fluid communication with the upper and lower processing regions; and
a lower slit valve, wherein the lower slit valve is configured to selectively allow transfer of a substrate into the lower processing region.

9. The substrate processing chamber of claim 8, wherein the substrate processing chamber is a degas chamber.

10. The substrate processing chamber of claim 6, wherein the upper and lower processing regions are centrally offset.

11. The substrate processing chamber of claim 10, further comprising:
an upper substrate support heater disposed within the upper processing region, wherein the upper substrate support heater has a plurality of apertures extending therethrough;
a lower substrate support heater disposed within the lower processing region, wherein the lower substrate support heater has a plurality of apertures extending therethrough.

12. The substrate processing chamber of claim 11, further comprising:
an upper substrate lifting device having a lift pin aligned with one of the plurality of apertures in the upper substrate support heater, wherein the upper substrate lifting device is vertically movable; and
a lower substrate lifting device having a lift pin aligned with one of the plurality of apertures in the lower substrate support heater, wherein the lower substrate lifting device is vertically movable.

13. The substrate processing chamber of claim 6, further comprising:
an upper diffuser configured to selectively apply a flow of gas into the upper processing region; and
a lower diffuser configured to selectively apply a flow of gas into the lower processing region.

14. The substrate processing chamber of claim 13, wherein the upper processing regions is isolated from the lower processing region.

15. A substrate processing system, comprising:
a load lock chamber;
a transfer module; and
a processing chamber, wherein the processing chamber comprises:
a port block; and
a main chamber body, wherein the main chamber body forms an upper processing region overlapping a lower processing region and wherein the upper and lower processing regions are isolated from one another and centrally offset.

16. The substrate processing system of claim 15, wherein the transfer module further comprises:
a transfer chamber having a square horizontal profile and a transfer robot contained therein for transferring substrates between the load lock chamber and the processing chamber; and
a vacuum extension chamber, wherein the vacuum extension chamber is configured to interface between a vacuum system and the transfer chamber.

17. The substrate processing system of claim 16, wherein the processing chamber further comprises:
an upper slit valve configured to selectively allow access to the upper processing region;
an upper substrate support heater configured in the upper processing region;
a lower substrate support heater configured in the lower processing region;
an upper diffuser configured to direct gas flow from an inert gas source into the upper processing region; and
a lower diffuser configured to direct gas flow from an inert gas source into the lower processing region.

18. The substrate processing system of claim 16, wherein the processing chamber further comprises:
an upper lid member sealingly engaged with the main chamber body over the upper processing region, wherein the upper lid member is removable to allow access to the upper processing region; and
a lower bottom member sealingly engaged with the main chamber body under the lower processing region, wherein the lower bottom member pivots to allow access to the lower processing region.

19. A method for degassing substrates in a cluster tool, comprising:
transferring a first substrate from a load lock chamber to an upper processing region of a degas chamber via a transfer robot;
processing the first substrate in the upper processing region of the degas chamber;
transferring a second substrate from the load lock chamber to a lower processing region of the degas chamber via the transfer robot while the first substrate is being processed; and
starting the processing of the second substrate in the lower processing region prior to completing the processing of the first substrate,
wherein the upper processing region overlaps and is centrally offset from the lower processing region.
